(19) United States
(12) Patent Application Publication
(10) Pub. No.: US 2011/0149543 A1
(43) Pub. Date: Jun. 23, 2011

(54) PRINTED WIRING BOARD CONNECTION STRUCTURE

(76) Inventors: Takeshi Kamoi, Kyoto (JP); Junichi Hasegawa, Kashiwara (JP); Jun Kumagai, Suita (JP); Kenji Sato, Himeji (JP)

(21) Appl. No.: 12/971,150

(22) Filed: Dec. 17, 2010

(30) Foreign Application Priority Data
Dec. 17, 2009 (JP) 2009-286717

(51) Int. Cl. H05K 1/14

(52) U.S. Cl. 361/803

(57) ABSTRACT

A printed wiring board connection assembly includes a first printed wiring board and a plurality of connecting pieces having a first connecting pattern made of an electrically conductive material formed on first and second opposing surfaces. A second printed wiring board has a plurality of connecting holes shaped to receive respective connecting pieces and having second connecting patterns arranged to correspond with the first connecting patterns of the respective connecting pieces. Each of the connecting pieces has one or more through-holes extending between the opposing surfaces of the respective connecting pieces and positioned such that upon receiving of the connecting pieces by the respective connecting holes a portion of at least one through-hole is exposed proximate the first surface of the second printed wiring board and a portion of at least one through-hole is exposed proximate the second surface of the second printed wiring board.

A portion of the disclosure of this patent document contains material that is subject to copyright protection. The copyright owner has no objection to the reproduction of the patent document or the patent disclosure, as it appears in the U.S. Patent and Trademark Office patent file or records, but otherwise reserves all copyright rights whatsoever.

### CROSS-REFERENCES TO RELATED APPLICATIONS

This application claims benefit of the following patent application(s) which is/are hereby incorporated by reference: Japan Patent Application No. 2009-286717, filed Dec. 17, 2009.

### STATEMENT REGARDING FEDERALLY SPONSORED RESEARCH OR DEVELOPMENT

Not Applicable

### REFERENCE TO SEQUENCE LISTING OR COMPUTER PROGRAM LISTING APPENDIX

Not Applicable

### BACKGROUND OF THE INVENTION

The present invention relates generally to a printed wiring board connection structure. More particularly, the present invention relates to a structure that electrically and mechanically couples a plurality of printed wiring boards.

There is conventionally known a technique for making an electrical and mechanical connection between a printed wiring board (motherboard) mounted with various integrated circuits and other electronic circuit components and a printed wiring board (daughter-board) constituting an integrated circuit such as a hybrid integrated circuit (HIC). Some conventional examples of such a printed wiring board connection structure are described herein with reference to FIGS. 4A-4C. Note that in the following description a direction between the top and bottom in, for example, FIG. 4A is defined as a vertical direction.

In a first conventional example, as illustrated in FIGS. 4A and 4B, a daughter-board 100 is provided with a plurality of external terminals 300 each of which protrudes from one end portion (lower end portion) of the daughter-board 100 itself and has a substantially L-shaped cross section. Also, a motherboard 200 is provided with a plurality of through-holes (not illustrated) into which the external terminals 300 are to be inserted. Accordingly, by inserting the external terminals 300 into the through-holes and soldering them with solder 400 on a lower surface side of the motherboard 200, the respective boards 100 and 200 are electrically and mechanically connected to each other.

The respective boards 100 and 200 connected in this manner are, as illustrated in FIG. 4C, enclosed in a case 500 which may be filled with resin 600 for improved insulating, radiation, and waterproof properties. By soldering from the lower surface side of the motherboard 200 in accordance with the above-described configuration, the solder 400 moves up from a lower surface to an upper surface of the motherboard 200 via the through-holes, thereby completely filling in the through-holes. However, a problem in the above example is that the daughter-board 100 is increased in size through the inclusion of the external terminals 300.

In a second conventional example, as illustrated in FIG. 5A, a daughter-board 101 is provided with a plate-like connecting piece 102 that protrudes from one end edge (lower end edge) of the daughter-board 101 itself and is formed with pluralities of connecting patterns 301 on both surfaces in a thickness direction thereof (i.e., transverse to the lower end edge of the board 101). Also, the motherboard 201 is provided with a connecting hole 202 into which the connecting piece 102 is to be inserted. Accordingly, by inserting the connecting piece 102 into the connecting hole 202, and soldering the connecting patterns 301 to connecting patterns (not illustrated) on a lower surface side of the motherboard 201, the respective boards are electrically and mechanically connected to each other.

The respective boards 101 and 201 connected in this manner are, as illustrated in FIG. 5B, enclosed in a case 501 which may be filled with resin 601 for improved insulating, radiation, and waterproof properties. An additional positioning member may be provided that, to prevent an inserting position of the daughter-board 101 into the motherboard 201 from being displaced, positions the daughter-board 101 with respect to the motherboard 201.

In the example shown in FIGS. 5A-B, the connecting patterns 301 are provided on the daughter-board 101 to thereby constitute the connecting piece 102, so that it is not necessary to mount external terminals 300 on the daughter-board 100 as in the first conventional example (FIGS. 4A-C), and therefore the daughter-board 101 is not increased in size. However, in the second conventional example, the connecting patterns 301 are provided only on first and second (i.e., inner and outer) surfaces in the thickness direction of the connecting piece 102 (i.e., in a direction transverse to the lower end edge of the daughter-board 101). For this reason, as illustrated in FIG. 5C), the amount of the solder 401 in sites near both surfaces in a thickness direction (i.e., upper and lower surfaces) of the motherboard 201 is insufficient. When the resin 601 is applied to fill in the case 501, the resin 601 is expanded or contracted by temperature differences occurring between operating and non-operating circuit states, and thereby stresses are applied to connections of the respective boards 101 and 201 in directions indicated by arrows A and B in FIG. 5C. Cracks are therefore likely to occur at the above connection sites where the amount of the solder 401 is insufficient.

In a third conventional example, as illustrated in FIGS. 6A and 6B, a daughter-board 103 is provided with a plurality of connecting pieces 104 that protrude from one end edge (lower end edge) of the daughter-board 103. Also, a motherboard 203 is provided with a plurality of connecting holes (not illustrated) into which the respective connecting pieces are to be inserted. Accordingly, by inserting the connecting pieces 104 into the connecting holes, and soldering them on a lower surface side of the motherboard 203, the respective boards 103 and 203 are electrically and mechanically connected to each other. Note that the entire surface of each of the connecting pieces 104 is covered with an electrically conductive material, or more particularly metal, and the cover constitutes a connecting pattern. For this reason, upon soldering from the lower surface side of the motherboard 203, solder moves up to an upper surface of the motherboard 203 through the connecting holes, and completely fills in the connecting holes. Accordingly, and as distinguished from the previously described examples, cracks are unlikely to occur, which results in good and reliable electrical connections between the respective boards.

However, for a configuration as described with respect to FIGS. 6A and 6B, the entire surface of each of the connecting pieces 104 needs to be supplied with the cover made of the electrically conductive material. Therefore not only both surfaces in a thickness direction (e.g., front and back surfaces) of each of the connecting pieces 104, but also side surfaces should be applied with the cover. For this reason, there is a problem that the labor necessary to manufacture the daughter-board 103 is increased, which makes it relatively difficult to manufacture the board.

### BRIEF SUMMARY OF THE INVENTION

Various embodiments of a printed wiring board connection structure and assembly are provided herein that enables a board to be easily manufactured and with good and reliable electrical connections.

In one embodiment, a printed wiring board connection assembly includes a first printed wiring board having a plurality of connecting pieces, each of which includes a first connecting pattern made of an electrically conductive material formed on first and second opposing surfaces. A second printed wiring board has a plurality of connecting holes extending between first and second opposing surfaces, each of which is shaped to receive a respective connecting piece and has a second connecting pattern made of an electrically conductive material and arranged to correspond with the first connecting pattern of the respective connecting piece so received. Each of the connecting pieces further includes a plurality of through-holes extending between the first and second opposing surfaces of the respective connecting pieces and spaced at predetermined intervals. Upon receiving of the connecting pieces by the respective connecting holes a portion of at least one of the through-holes is exposed proximate the first surface of the second printed wiring board and a portion of at least one of the other through-holes is exposed proximate the second surface of the second printed wiring board.

In another embodiment, a printed wiring board connection assembly in accordance with the present invention includes a first printed wiring board having a plurality of connecting members extending from a first side. Each connecting member has a first connecting pattern made of an electrically conductive material formed on first and second opposing surfaces of the member. A second printed wiring board has a plurality of connecting holes extending between first and second opposing surfaces of the second printed wiring board. Each of the connecting holes is shaped to receive a respective connecting piece and includes a second connecting pattern made of an electrically conductive material and arranged to correspond with the first connecting pattern of the respective connecting piece. Each of the connecting pieces further includes a through-hole extending between the first and second opposing surfaces of the respective connecting pieces and having an elliptical shape with respect to either of the opposing surfaces. Upon receiving the connecting pieces by the respective connecting holes a first portion of the through-hole is exposed proximate the first surface of the second printed wiring board and a second portion of the through-hole is exposed proximate the second surface of the second printed wiring board.

In another embodiment of the present invention, a printed wiring board assembly connection includes a daughter-board having a first side and a plurality of connecting pieces coupled to the first side. The connecting pieces are shaped and oriented so as to be received by a corresponding plurality of connecting holes in a motherboard. Each connecting piece further includes a connecting pattern made of an electrically conductive material formed on first and second opposing surfaces, and one or more through-holes extending from the first surface to the second opposing surface of the connecting piece and having an inner circumferential surface covered with an electrically conductive material. The one or more through-holes are further arranged such that upon the connecting piece being received by a corresponding connecting hole a portion of at least one of the one or more through-holes is partially exposed proximate each of a first and a second side of said connecting hole.

### BRIEF DESCRIPTION OF THE SEVERAL VIEWS OF THE DRAWINGS

FIGS. 1A and 1B are representative views of an embodiment of a printed wiring board connecting structure according to the present invention, in which FIG. 1A is a perspective view, and FIG. 1B is a front view in a condition where connecting pieces are inserted.

FIGS. 2A-C are representative views of a portion of the printed wiring board of FIG. 1 in a state after soldering, in which FIG. 2A is a front view, FIG. 2B is a side view, and FIG. 2C is a cross-sectional view.

FIGS. 3A-C are representative views of another embodiment of a printed wiring board connecting structure according to the present invention, in which FIG. 3A is an overall perspective view, FIG. 3B is a front view in a condition where connecting pieces are inserted, and FIG. 3C is a cross-sectional view of a portion of the printed wiring board.

FIGS. 4A-C are representative views of an example of a printed wiring board connecting structure as previously known in the art, in which FIG. 4A is a front view, FIG. 4B is a side view, and FIG. 4C) is a cross-sectional view in a condition where respective printed wiring boards are enclosed in a case.

FIGS. 5A-C are representative views of another example of a printed wiring board connecting structure as previously known in the art, in which FIG. 5A is a perspective view, FIG. 5B is a cross-sectional view in a condition where respective printed wiring boards are enclosed in a case, and FIG. 5C is a cross-sectional view of a portion of the printed wiring board.

FIGS. 6A and 6B are representative views of another example of a printed wiring board connecting structure as previously known in the art, in which

FIG. 6A is a perspective view, and FIG. 6B is a front view of a daughter-board.

### DETAILED DESCRIPTION OF THE INVENTION

Throughout the specification and claims, the following terms take at least the meanings explicitly associated herein, unless the context dictates otherwise. The meanings identified below do not necessarily limit the terms, but merely provide illustrative examples for the terms. The meaning of “a,” “an,” and “the” may include plural references, and the meaning of “in” may include “in” and “on.” The phrase “in one embodiment,” as used herein does not necessarily refer to the same embodiment, although it may.

The terms “coupled” and “connected” as used herein may mean at least either a direct connection between recited items or an indirect connection through one or more passive or active intermediary devices, and further unless otherwise stated may include a temporary connection such as may be obtained for example through the use of a general adhesive, a semi-permanent connection such as may be provided for example through the use of a mechanical fastener, or a permanent connection such as may be obtained for example by soldering of the recited items together.

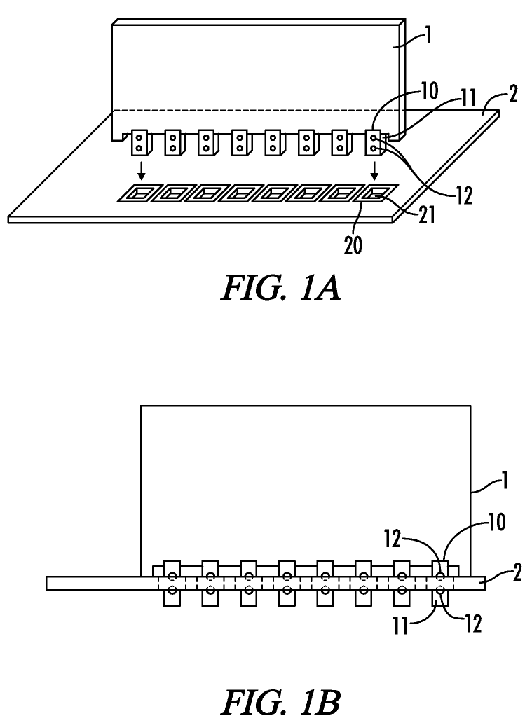

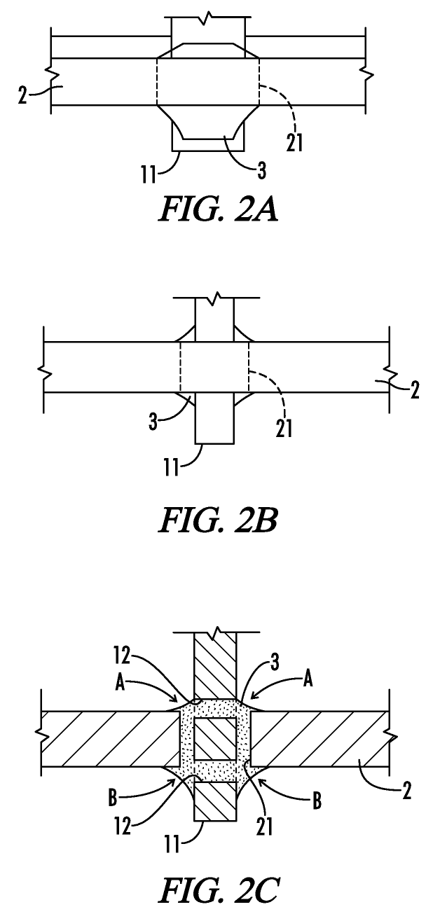

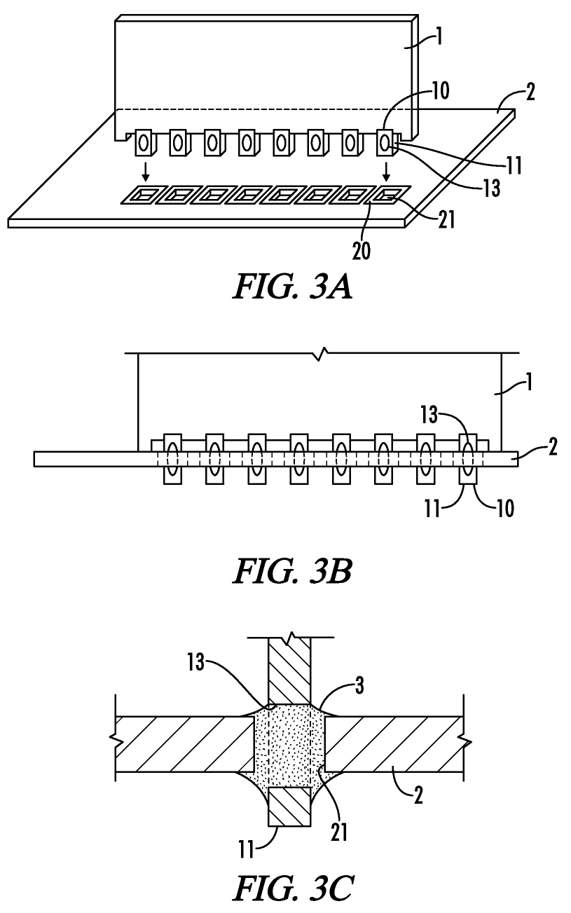

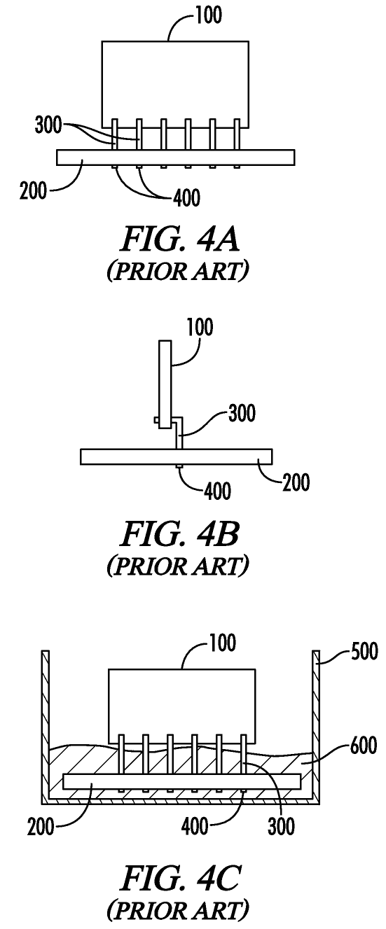

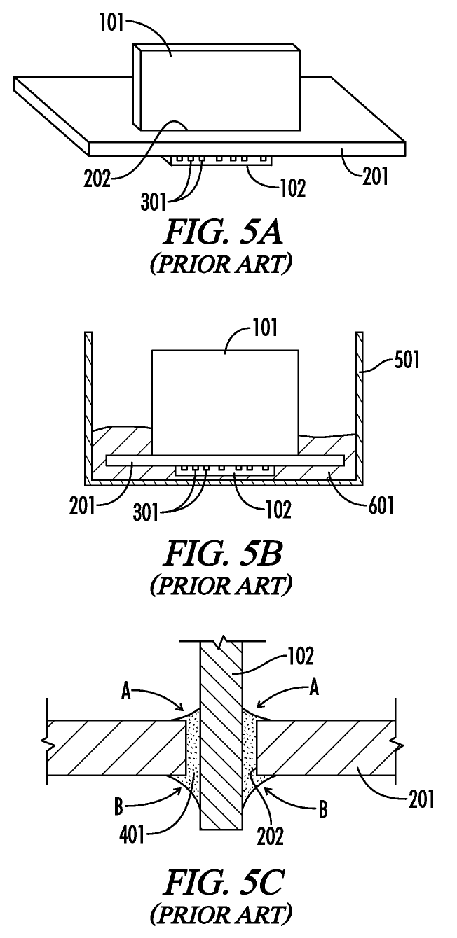

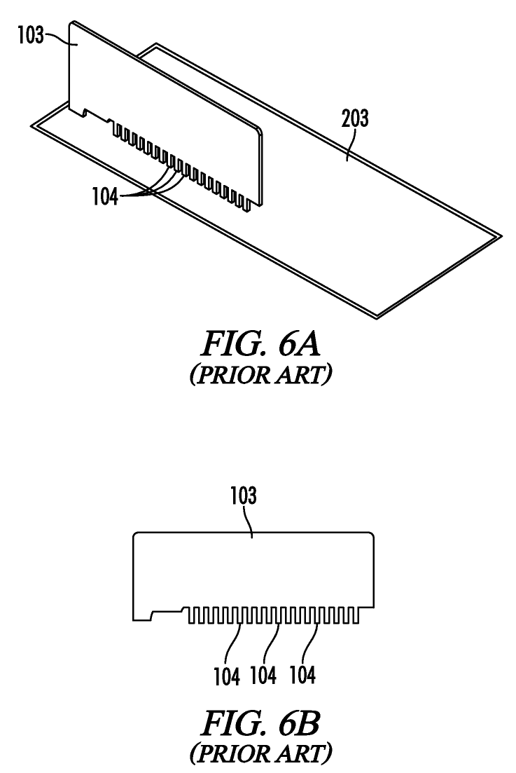

Referring generally to FIGS. 1A-C, FIGS. 2A-C, and FIGS. 3A-C, various embodiments of a printed wiring board connection structure may be described herein. Where the various figures may describe embodiments sharing various common elements and features with other embodiments, similar elements and features are given the same reference numerals and redundant description thereof may be omitted below.

Note further that, in the following description, directions between the top and bottom and between the right and left as represented in FIG. 1B (and equivalent figures throughout the remainder of this description) may be respectively defined as vertical and horizontal directions, and directions toward front and rear sides of the diagram may be respectively defined as front and rear directions. These directions are not intended as limiting on the scope of the present invention or the orientation thereof in various end positions, but are merely intended for the purpose of explanation herein.

An embodiment of a printed wiring board connection structure as illustrated in FIGS. 1A and 1B includes a daughter-board 1 serving as a first printed wiring board and a motherboard 2 serving as a second printed wiring board, in which the respective boards are electrically and mechanically coupled or connected by, for example, soldering.

The daughter-board 1 may be, for example, a hybrid integrated circuit (HIC) and further includes a plurality of (eight shown in FIG. 1A) connecting pieces 11 integrally protruding from one end edge (i.e., a lower end edge) of the daughter-board 1. Each of the connecting pieces 11 may be a rectangular plate-like member, and both surfaces (i.e., front and rear surfaces) in a thickness direction thereof (i.e., a direction extending laterally from a surface of the motherboard 2 when the daughter-board 1 is connected thereto) are formed with a first connecting pattern 10 made of an electrically conductive material. Also, in each of the connecting pieces 11, first and second through-holes 12 are provided at a predetermined interval along a lateral axis (i.e., vertical axis as represented in FIG. 1B of the connecting piece 11, each of which penetrates in the thickness direction (i.e., from a front surface to a rear surface of the connecting piece) and may be circular-shaped in a plan view. An inner circumferential surface of each of the through-holes 12 may further be covered with an electrically conductive material.

The motherboard 2 may have various integrated circuits and other electronic circuit components mounted thereon, and constitutes a substantially planar member having a plurality (eight in FIG. 1A) of connecting holes 21 defined therein and that penetrate through the board 2 in a thickness direction (i.e., from a front/upper surface to a rear/bottom surface) so as to receive the respective connecting pieces 11. Each of the connecting holes 21 is rectangular shaped in a plan view, and a circumferential part and inner circumferential surface thereof is formed with a second connecting pattern 20 that is arranged to be electrically connected to the first connecting pattern 10 on an associated connecting piece 11 and made of an electrically conductive material.

Connections between the respective boards 1 and 2 in the present embodiment may now be further described with reference to FIGS. 2A and 2B. First, the various connecting pieces 11 of the daughter-board 1 are inserted into respective connecting holes 21 of the motherboard 2 from an upper surface side of the motherboard 2. The first connecting patterns 10 of the connecting pieces 11 and the second connecting patterns 20 of the connecting holes 21 are joined to each other by soldering. Note that, as a method for the soldering, a flow method may be employed as is conventionally known in the art. That is, soldering may be performed by passing the respective boards 1 and 2 through a solder bath with the respective connecting pieces 11 being inserted into the respective connecting holes 21, and directing flow from a solder jet generated in the solder bath toward a lower surface of the motherboard 2. Solder 3 passes through the respective connecting holes 21 to reach the upper surface of the motherboard 2, and on both of the upper and lower surfaces of the motherboard 2, forms solder fillets as illustrated in FIGS. 2A and 2B.

Note that, at the time of the soldering, portions of the through-holes 12 are exposed outside of (above and/or below) the connecting holes 21. In particular, in the present embodiment, as illustrated in FIG. 1B, portions of the upper through-holes 12 are exposed proximate the upper surface side of the motherboard 2, and portions of the lower through-holes 12 are exposed proximate the lower surface side of the motherboard 2. By performing the soldering in this state, the daughter-board 1 and the motherboard 2 are joined to each other in the form as illustrated in FIG. 2C.

During a soldering process for the configuration as described above, the solder 3 fills in the through-holes 12 near the upper and lower surfaces of the motherboard 2 and portions of the connecting holes 21 on either side of the connecting pieces 11 are joined by the solder through the through-holes 12, and therefore in the joint areas a sufficient amount of the solder 3 can be ensured to enhance joint strength. Note that if the respective boards 1 and 2 are contained in a case (not illustrated) which is then filled with resin (also not illustrated), the resin may expand or contract by a temperature difference occurring between operating and non-operating circuit states, and thereby connecting sites (solder joints) of the respective boards 1 and 2 may be stressed. In such a case, the stress may be applied in directions indicated by arrows A and B illustrated in FIG. 2C. However, in an embodiment as described above, the joint strength in the connecting sites is enhanced, and therefore even if an external stress is applied to the connecting sites a failure such as a crack may be substantially prevented from occurring.

In various embodiments as described above, covers may further be unnecessary and therefore not applied to entire surfaces of the connecting pieces 11 to achieve the desired joint strength.

In an embodiment as shown for example in FIGS. 1A and 1B, two through-holes 12 are provided in each of the connecting pieces 11. However, the number of the through-holes 12 is not limited. In the case of providing three or more through-holes 12, if at least two of the through-holes 12 have the above configuration, the same effect as above can be produced.

Referring now to FIGS. 3A to 3C, an embodiment a printed wiring board connecting structure according to the present invention may be described having a fundamental configuration similar to the embodiment of FIGS. 1A and 1B, and therefore common features are denoted by the same numerals to omit redundant description. In addition, in the following description, directions between the top and bottom and between the right and left in FIG. 3B are respectively defined as vertical and horizontal directions, and directions toward front and rear sides of the diagram are respectively defined as front and rear directions.

In an embodiment as shown in FIGS. 3A and 3B, each of the connecting pieces 11 has one through-hole 13. The through-hole 13 has an elliptical shape in a plan view or otherwise with respect to front and rear sides of the connecting piece, of which a major axis is in a thickness direction (vertical direction) of the motherboard 2, and configured such that where each of the connecting pieces 11 is inserted into each of connecting holes 21, both of upper and lower end portions thereof are respectively exposed on upper and lower sides of the motherboard 2. When a soldering process is performed in this state, a daughter-board 1 and the motherboard 2 are joined to each other in the form as illustrated in FIG. 3C.

Thus, in a soldering process for the configuration as described above, the solder 3 fills in the through-holes 13 near the upper and lower surfaces of the motherboard 2 and portions of the connecting hole 21 on either side of the connecting pieces 11 are joined by the solder through the through-holes 13. Therefore, in the joint areas a sufficient amount of the solder 3 can be ensured to enhance joint strength. Also, the volume inside the through-hole 13, filled with the solder 3, is larger than that of the through-hole 12 of an embodiment having a plurality of substantially circular holes, and therefore the respective boards 1 and 2 can be more tightly joined to each other.

During a soldering process associated with each of the above-described embodiments, the solder 3 should flow into the through-holes 12 or 13 to fill the through-holes 12 or 13. For this purpose, it is better for a horizontal (i.e., width direction of the connecting pieces 11) diameter of the through-holes 12 or 13 to be relatively large, and preferably the diameter is 0.3 mm or greater. Also, the connecting pieces 11 should be provided with sufficient spaces respectively for providing the through-holes 12 or 13 and for the first connecting patterns 10 for making the electrical connections between the daughter-board 1 and the motherboard 2. For this purpose, the width of the connecting pieces 11 is preferably 1.0 mm or more. Further, to ensure reliable electrical connections, the distance between an edge surface of each of the connecting pieces 11 and an edge surface of each of the through-holes 12 or 13 in the width direction of the connecting piece is preferably 0.2 mm or more.

In each of the above-described embodiments, the soldering process is performed using a flow method. However, soldering may be performed using other equivalent methods, and for example a soldering iron may be used to individually solder the respective connecting pieces 11. Even in such a case, it should be appreciated that the same effect as above can be produced.

Thus, although there have been described particular embodiments of the present invention of a new and useful Printed Wiring Board Connecting Structure it is not intended that such references be construed as limitations upon the scope of this invention except as set forth in the following claims.

What is claimed is:

1. An assembly comprising:
a first printed wiring board having a plurality of connecting pieces, each connecting piece having a first connecting pattern made of an electrically conductive material formed on first and second opposing surfaces;
a second printed wiring board having a plurality of connecting holes extending between first and second opposing surfaces of the second printed wiring board, each of the connecting holes shaped to receive a respective one of the connecting pieces and having a second connecting pattern made of an electrically conductive material and arranged to correspond with the first connecting pattern of the respective connecting piece so received; and
each of the connecting pieces further comprises a plurality of through-holes extending between the first and second opposing surfaces of the respective connecting pieces and spaced at predetermined intervals, wherein upon receiving the connecting pieces by the respective connecting holes, a portion of at least one of the through-holes is exposed proximate the first surface of the second printed wiring board and a portion of at least one of the other through-holes is exposed proximate the second surface of the second printed wiring board.

2. The assembly of claim 1, wherein the through-holes for the connecting pieces respectively have inner circumferential surfaces covered with an electrically conductive material.

3. The assembly of claim 1, each connecting piece extending from a first side of the first printed wiring board, the first connecting pattern formed in a direction corresponding to an axis transverse to that of the first side of the first printed wiring board.

4. The assembly of claim 3, each connecting piece comprising a rectangular member being oblong in the direction of protrusion from the first side of the first printed wiring board.

5. The assembly of claim 1, the plurality of through-holes being circular in shape with respect to the first and second surfaces of the respective connecting pieces.

6. The assembly of claim 1, the first and second printed wiring boards effective to be electrically and mechanically coupled by at least one solder joint comprising solder filling each of the through-holes proximate the second printed wiring board in a particular connecting piece and further engaging the respective connecting hole on first and second opposing sides with respect to the connecting piece.

7. The assembly of claim 1, wherein the first printed wiring board comprises a hybrid integrated circuit.

8. An assembly comprising:
a first printed wiring board having a plurality of connecting members extending from a first side of the first printed wiring board, each connecting member having a first connecting pattern made of an electrically conductive material formed on first and second opposing surfaces; and
a second printed wiring board having a plurality of connecting holes extending between first and second opposing surfaces of the second printed wiring board, each of the connecting holes shaped to receive a respective one of the connecting members and having a second connecting pattern made of an electrically conductive material and arranged to correspond with the first connecting pattern of the respective connecting member so received,
each of the connecting members further comprising a through-hole extending between the first and second opposing surfaces of the respective connecting members and having an elliptical shape with respect to either of the opposing surfaces wherein upon receiving of the connecting members by the respective connecting holes a first portion of the through-hole is exposed proximate the first surface of the second printed wiring board and a second portion of the through-hole is exposed proximate the second surface of the second printed wiring board.

9. The assembly of claim 8, wherein the through-hole for each of the connecting members respectively has an inner circumferential surface covered with an electrically conductive material.

10. The assembly of claim 8, each connecting member extending from a first side of the first printed wiring board, the first connecting pattern formed in a direction corresponding to an axis transverse to that of the first side of the first printed wiring board.

11. The assembly of claim 10, the elliptical shape of the through-hole having a major diameter in a direction corresponding to the axis transverse to that of the first side of the first printed wiring board.

12. The assembly of claim 11, each connecting member comprising a rectangular member being oblong in the direction of protrusion from the first side of the first printed wiring board.

13. The assembly of claim 8, the first and second printed wiring boards effective to be electrically and mechanically coupled by at least one solder joint comprising solder filling the through-hole proximate the second printed wiring board in a particular connecting member and further engaging the respective connecting hole on first and second opposing sides with respect to the connecting member.

14. The assembly of claim 8, wherein the first printed wiring board comprises a hybrid integrated circuit.

15. An assembly comprising:
a daughter-board having a first side and a plurality of connecting pieces coupled to the first side, the connecting pieces shaped and oriented so as to be received by a corresponding plurality of connecting holes in a motherboard; and
each connecting piece further comprising
a connecting pattern made of an electrically conductive material formed on first and second opposing surfaces, and
one or more through-holes extending from the first surface to the second opposing surface of the connecting piece and having an inner circumferential surface covered with an electrically conductive material, the one or more through-holes further arranged such that upon the connecting piece being received by a corresponding connecting hole a portion of at least one of the one or more through-holes is partially exposed proximate each of a first and a second side of said connecting hole.

16. The assembly of claim 15, the connecting pattern of each connecting piece arranged so as to be connectable by soldering to a corresponding connecting pattern in the respective connecting hole.

17. The assembly of claim 15, each of the connecting pieces comprising a plurality of through-holes extending between the first and second opposing surfaces of the respective connecting pieces and spaced at predetermined intervals wherein upon receiving of the connecting pieces by the respective connecting holes a portion of at least one of the through-holes is exposed proximate the first surface of the motherboard and a portion of at least one of the other through-holes is exposed proximate the second surface of the motherboard.

18. The assembly of claim 15, each of the connecting pieces comprising a through-hole extending between the first and second opposing surfaces of the respective connecting pieces and having an elliptical shape with respect to either of the opposing surfaces wherein upon receiving of the connecting pieces by the respective connecting holes a first portion of the through-hole is exposed proximate the first surface of the motherboard and a second portion of the through-hole is exposed proximate the second surface of the motherboard.

19. The assembly of claim 15, each connecting piece extending from a first side of the first printed wiring board, the first connecting pattern formed in a direction corresponding to an axis transverse to that of the first side of the first printed wiring board.

20. The assembly of claim 3, each connecting piece comprising a rectangular member being oblong in the direction of protrusion from the first side of the first printed wiring board.
